(19) United States
(12) Patent Application Publication
(10) Pub. No.: US 2010/0000592 A1
(43) Pub. Date: Jan. 7, 2010

(54) Self-propelled Solar Tracking Apparatus with Multi-layer Solar Panel

(75) Inventor: Chien-Ho KO, TAIPEI (TW)

Correspondence Address: Chih Feng Yeh;BRIAN M. MCINNIS, 12th Floor, Ruttonjee House, 11 Duddell Street, Hong Kong, HK

(73) Assignee: NATIONAL PINGTUNG UNIVERSITY OF SCIENCE AND TECHNOLOGY, Pingtung (TW)

(21) Appl. No.: 12/424,538

(22) Filed: Apr. 16, 2009

(30) Foreign Application Priority Data
Jul. 2, 2008 (TW) 97124905

(51) Int. Cl. H01L 31/042; F24J 2/38

(52) U.S. Cl. 136/246; 126/573

(57) ABSTRACT

A self-propelled solar tracking apparatus includes a multi-layer solar panel, a body, a lifting device and a moving device. The multi-layer solar panel carries the solar cell modules and includes a first layer, a second layer and a third layer. The first layer includes a first track assembly and a second track assembly. The first track assembly locates at one side of the first layer, and the second track assembly locates at the opposite side of the first layer. The second layer locates above the first layer and slidiably connects to the first layer. The third layer locates above the second layer and slidably connects to the first layer. The body has a hollow space to retrieve the multi-layer solar panel. The lifting device connects the multi-layer solar panel with the body. The moving device demountably connects the bottom of the body.

### RELATED APPLICATIONS

This application claims priority to Taiwan Application Serial Number 97124905, filed Jul. 2, 2008, which is herein incorporated by reference.

### BACKGROUND

1. Field of Invention

The present invention relates to a solar apparatus, and particularly relates to a self-propelled solar tracking apparatus.

2. Description of Related Art

Solar cells have many applications, but the area of the solar cell panel restricts the supplied power. When combining the solar cell with apparatus, the limited surface area of the apparatus is a great trouble. On the other hand, the sunlight is not always perpendicular to the solar cell panel, and thus the photoelectric transmission efficiency is low. Therefore, a better solar cell device is pursued to solve the drawback mentioned above.

### SUMMARY

One aspect of the present invention is to provide a self-propelled solar tracking apparatus with multi-layer solar panel to increase the area of the solar cell modules.

According to one embodiment of the present invention, the self-propelled solar tracking apparatus includes a multi-layer solar panel, a body, a lifting device and a moving device. The multi-layer solar panel carries the solar cell modules and includes a first layer, a second layer and a third layer. The first layer includes a first track assembly and a second track assembly. The first track assembly locates at one side of the first layer, and the second track assembly locates at the opposite side of the first layer. The second layer locates above the first layer and slidiably connects to the first layer. The third layer locates above the second layer and slidably connects to the first layer. The body has a hollow space to retrieve the multi-layer solar panel. The lifting device connects the multi-layer solar panel with the body. The moving device demountably connects the bottom of the body.

### BRIEF DESCRIPTION OF THE DRAWINGS

The invention can be more fully understood by reading the following detailed description of the embodiment, with reference made to the accompanying drawings as follows:

FIG. 1 is a schematic view of the self-propelled solar tracking apparatus with multi-layer solar panel of one embodiment of the invention.

FIG. 2 is a schematic view of FIG. 1, showing that the multi-layer solar panel is retrieved in the body.

FIG. 3 is a schematic view for one embodiment of the first layer of FIG. 1.

FIG. 4 is a schematic view of the multi-layer solar panel, showing that the grooves are arranged up and down.

FIG. 5 is a schematic view of the multi-layer solar panel, showing that the grooves are arranged side by side.

FIG. 6 is a schematic view of the track assembly according to another embodiment of the invention.

FIG. 7 is a schematic view of the driving device of FIG. 6.

FIG. 8 is a schematic view of the lifting device of FIG. 1.

FIG. 9 is a schematic view of the moving device of FIG. 1.

### DETAILED DESCRIPTION

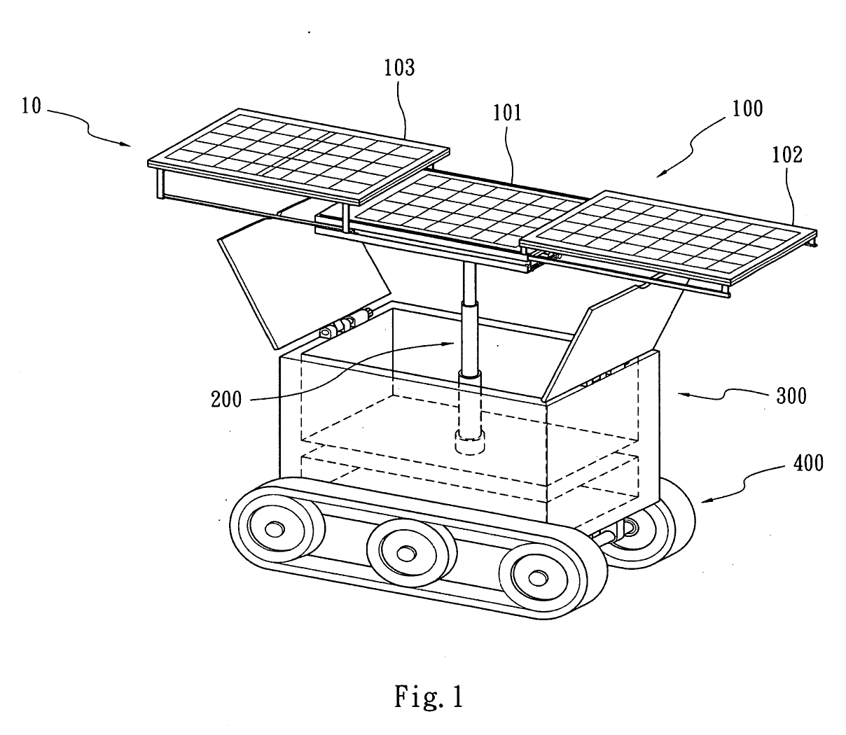

Referring to FIG. 1 for a schematic view of the self-propelled solar tracking apparatus with multi-layer solar panel of one embodiment of the invention, the self-propelled solar tracking apparatus 10 includes a multi-layer solar panel 100, a body 300, a lifting device 200 and a moving device 400. The multi-layer solar panel 100 carries the solar cell modules and includes a first layer 101, a second layer 102 and a third layer 103. The second layer 102 locates above the first layer 101 and slidiably connects to the first layer 101. The third layer 103 locates above the second layer 102 and slidably connects to the first layer 101. The body 300 has a hollow space to retrieve the multi-layer solar panel 100. The lifting device 200 connects the multi-layer solar panel 100 with the body 300. The moving device 400 demountably connects the bottom of the body 300.

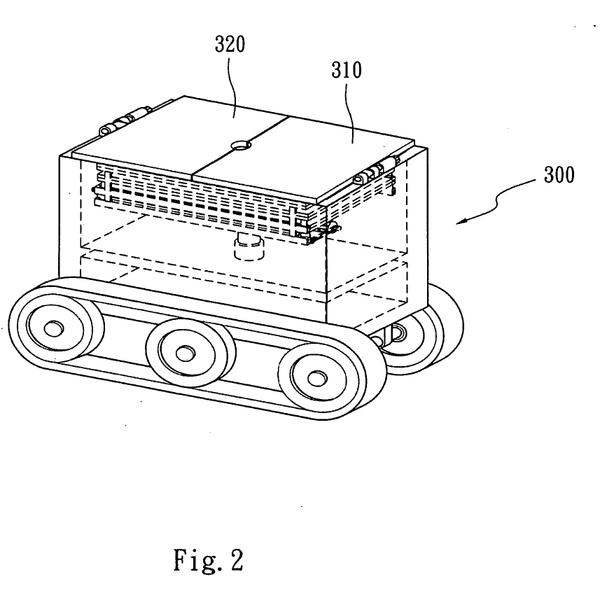

Referring to FIG. 2 for a schematic view of FIG. 1, the multi-layer solar panel 100 is retrieved in the body 300. The body 300 retrieves the multi-layer solar panel 100 in the hollow space, and further covers the hollow space by the right cover 310 and the left cover 320. Therefore, the right cover 310 and the left cover 320 protect the solar cell modules of the multi-layer solar panel 100 from unnecessary wearing and impacts.

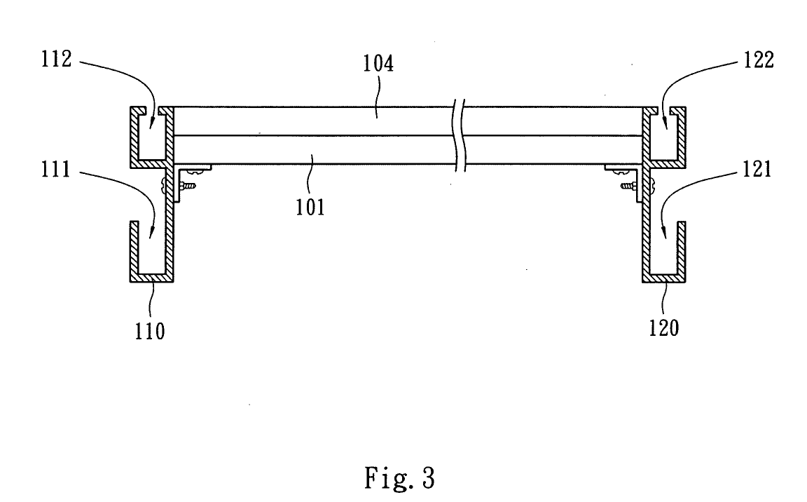

Referring to FIG. 3 for a schematic view for one embodiment of the first layer 101 of FIG. 1, the first layer 101 includes a first track assembly 110 and a second track assembly 120. The first track assembly 110 locates at one side of the first layer 101, and the second track assembly 120 locates at the opposite side of the first layer 101. The first track assembly 110 includes a first groove 111 and a second groove 112, the second track assembly 120 includes a third groove 121 and a fourth groove 122. The first layer 101 carries the solar cell module 104. The first groove 111 and the second groove 112 can be arranged up-and-down or side-by-side. In FIG. 3 for instance, the embodiment takes the up-and-down structure.

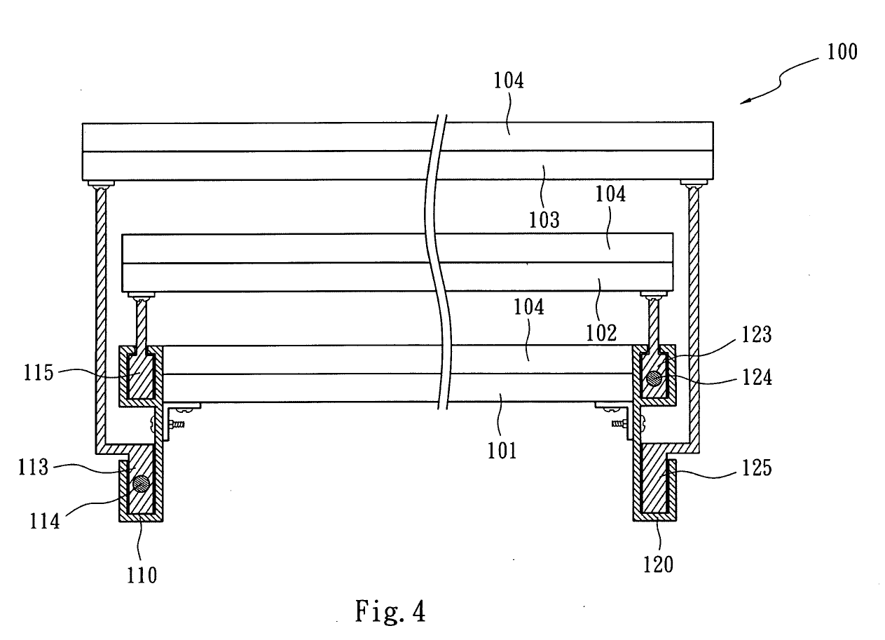

Referring to FIG. 4 for a schematic view of the multi-layer solar panel 100, the grooves are arranged up and down. A slide block 115 is inserted into the second groove 112, and further extended to support one side of the second layer 102. Similarly, a slide block 123 is inserted into the fourth groove 122, and further extended to support the opposite side of the second layer 102. And therefore, the second layer 102 slidably connects to the first layer 101 via the first track assembly 110 and the second track assembly 120.

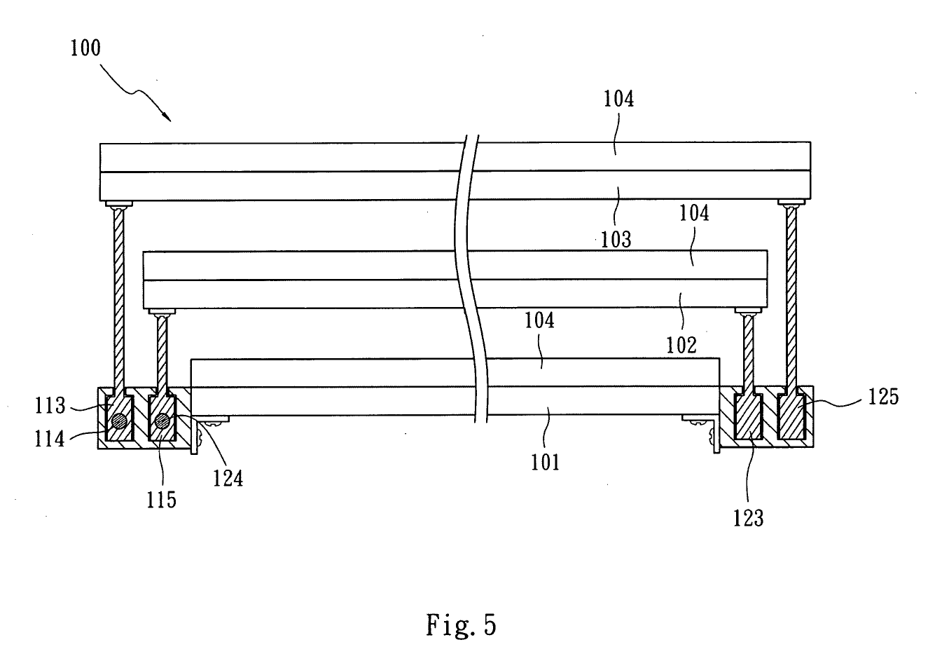

Referring to FIG. 5 for a schematic view of the multi-layer solar panel 100, the grooves are arranged side by side. A slide block 113 is inserted into the first groove 111, and further extended to support one side of the third layer 103. Similarly, a slide block 125 is inserted into the third groove 121, and further extended to support the opposite side of the third layer 103. And therefore, the third layer 103 slidably connects to the first layer 101 via the first track assembly 110 and the second track assembly 120.

On the other hand, a transmission screw 124 is inserted in either the second groove 112 or the fourth groove 122 to move the second layer 102 automatically. For instance, the transmission screw 124 is engaged with the slide block 115. And therefore, the slide block 115 is moved while a driver rotates the transmission screw 124. Similarly, a transmission screw 114 is inserted in either the first groove 111 or the third groove 121 to move the third layer 103 automatically.

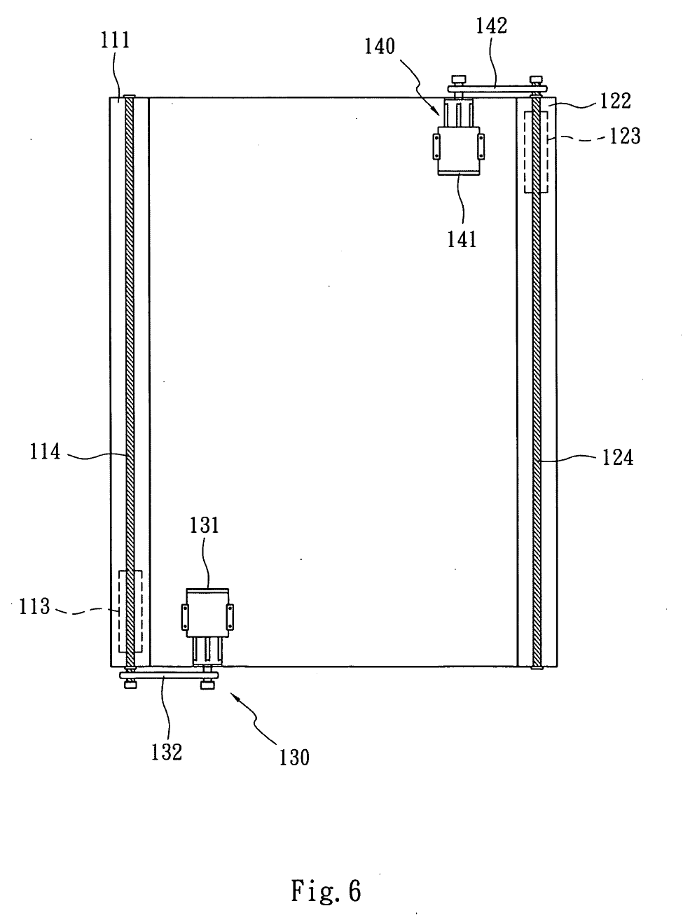

Referring to FIG. 6 for a schematic view of the track assembly, the first driving device 130 connects the transmission screw 114 to move the slide block 113 and further moves the third layer 103. A second driving device 140 connects the transmission screw 124 to move the slide block 123 and further moves the second layer 102. The first driving device 130 includes a driver 131 and a transmission assembly 132. The driver 131 is a motor, and the transmission assembly 132 connects the transmission screw 114 with the motor. The transmission assembly 132 transmits the power of the driver 131 to the transmission screw 114.

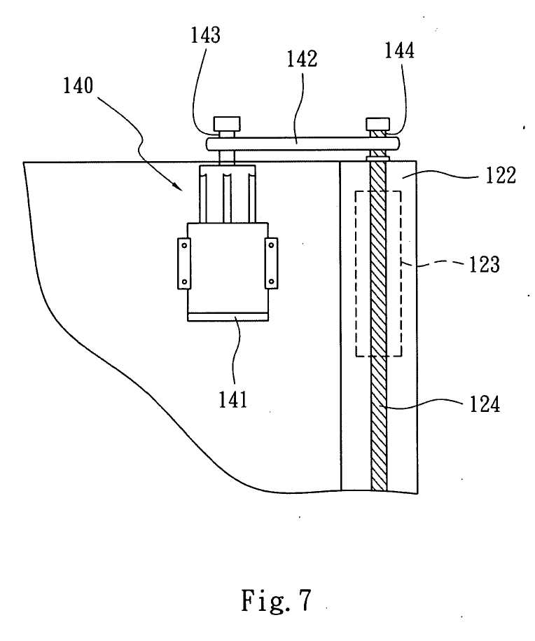

Referring to FIG. 7 for a schematic view of the driving device of FIG. 6, the second driving device 140 includes a driver 141 and a transmission assembly 142. The transmission assembly 142 includes a first part 143 to connect the driver 141, and a second part 144 to connect the transmission screw 124. The first part 143 and the second part 144 can be achieved by two gears engaged with each other, or also can be achieved by two rollers connected with each other by a belt.

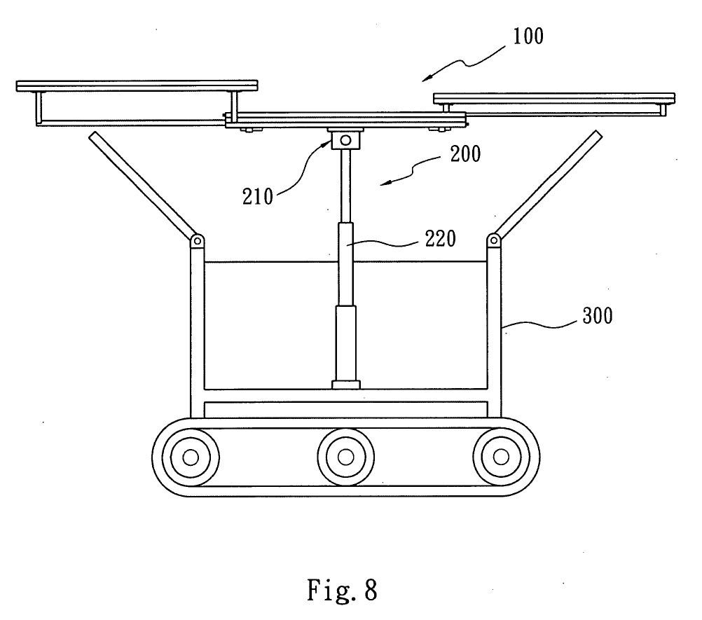

Referring to FIG. 8 for a schematic view of the lifting device of FIG. 1, the lifting device 200 includes a universal joint 210 and a telescopic pipe 220. The universal joint 210 rotates the multi-layer solar panel 100 to track the sunlight. And the telescopic pipe 220 connects the universal joint 210 with the body 300.

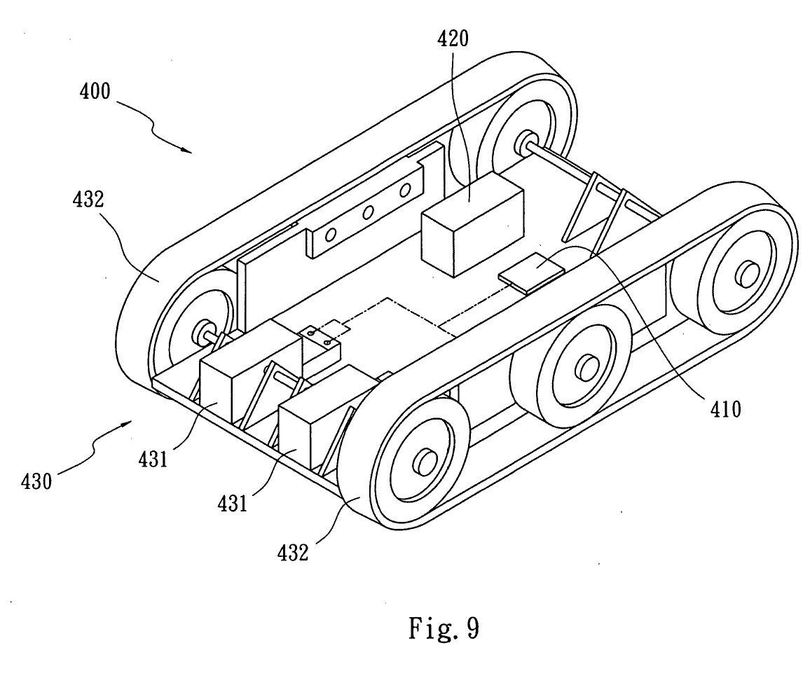

Referring to FIG. 9 for a schematic view of the moving device of FIG. 1, the moving device 400 includes a control unit 410, a power unit 420 and a driving assembly 430. The control unit 410 controls the lifting device 200, the first track assembly 110 and the second track assembly 120, and therefore controls the lifting, the rotation and the extending of the multi-layer solar panel 100. Therefore, the control unit 410 controls the universal joint 210 to rotate the multi-layer solar panel 100 to track the sunlight, and keeps the multi-layer solar panel 100 perpendicular with the sunlight.

The driving assembly 430 includes a driver 431 and a wheel 432. In some situations, such as snowy and muddy surfaces, a caterpillar band can be mounted on the wheel 432 to enhance the movability. The moving device 400 is demountable, in other words, the body 300 can be combined with a weeder or a golf ball collecting machine.

While the present invention has been described by way of examples and in terms of a preferred embodiment, it is to be understood that the present invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A self-propelled solar tracking device comprising:
a multi-layer solar panel to carry the solar cell modules, the multi-layer solar panel comprising:
a first layer comprising a first track assembly and a second track assembly located at two sides of the first layer respectively;
a second layer located above the first layer and slidiably connected to the first layer; and
a third layer located above the second layer and slidably connected to the first layer;
a body comprising a hollow space to retrieve the multi-layer solar panel;
a lifting device connected between the multi-layer solar panel and the body; and
a moving device removably connected at the bottom of the body.

2. The self-propelled solar tracking device of claim 1, the first track assembly comprising a first groove and a second groove, the second track assembly comprising a third groove and a fourth groove.

3. The self-propelled solar tracking device of claim 2, the first track assembly comprising a first slide block located in the first groove to connect one side of the third layer, and the second track assembly comprising a second slide block located in the third groove to connect the opposite side of the third layer.

4. The self-propelled solar tracking device of claim 3, the first track assembly comprising a transmission screw, the transmission screw is located in the first groove and engaged with the first slide block.

5. The self-propelled solar tracking device of claim 4, the first track assembly comprising a first driving device, the first driving device is for rotating the transmission screw.

6. The self-propelled solar tracking device of claim 3, the second track assembly comprising a transmission screw, the transmission screw is located in the third groove and engaged with the second slide block.

7. The self-propelled solar tracking device of claim 6, the second track assembly comprising a first driving device, the first driving device is for rotating the transmission screw.

8. The self-propelled solar tracking device of claim 2, the first track assembly comprising a first slide block located in the second groove to connect one side of the second layer, and the second track assembly comprising a second slide block located in the fourth groove to connect the opposite side of the second layer.

9. The self-propelled solar tracking device of claim 8, the first track assembly comprising a transmission screw, the transmission screw is located in the second groove and engaged with the first slide block.

10. The self-propelled solar tracking device of claim 9, the first track assembly comprising a second driving device, the second driving device is for rotating the transmission screw.

11. The self-propelled solar tracking device of claim 8, the second track assembly comprising a transmission screw, the transmission screw is located in the fourth groove and engaged with the second slide block.

12. The self-propelled solar tracking device of claim 11, the second track assembly comprising a second driving device, the second driving device is for rotating the transmission screw.

13. The self-propelled solar tracking device of claim 1, the lifting device comprising a universal joint to rotate the multi-layer solar panel.

14. The self-propelled solar tracking device of claim 13, the lifting device comprising a telescopic pipe, one terminal of the telescopic pipe connects the universal joint and the other terminal of the telescopic pipe connects the body.

15. The self-propelled solar tracking device of claim 1, the moving device comprising a control unit to control the lifting device, the first track assembly and the second track assembly.

16. The self-propelled solar tracking device of claim 1, the moving device comprising a power unit and a driving assembly.

17. The self-propelled solar tracking device of claim 16, the driving assembly comprising a driver and a wheel.

18. The self-propelled solar tracking device of claim 16, the driving assembly comprising a driver and a caterpillar band.

19. The self-propelled solar tracking device of claim 1, wherein the moving device is a weeder.

20. The self-propelled solar tracking device of claim 1, wherein the moving device is a golf ball collecting machine.
